(19) United States
(12) Patent Application Publication
(10) Pub. No.: US 2008/0006936 A1
(43) Pub. Date: Jan. 10, 2008

(54) Superfine-circuit semiconductor package structure

(76) Inventor: Shih-Ping Hsu, Hsin-chu (TW)

Correspondence Address: SAWYER LAW GROUP LLP, P O BOX 51418, PALO ALTO, CA, 94303, US

(21) Appl. No.: 11/484,055

(22) Filed: Jul. 10, 2006

(51) Int. Cl. H01L 23/12

(52) U.S. Cl. 257/731

(57) ABSTRACT

A superfine-circuit semiconductor package structure includes a carrier board, a support board having at least one through hole and mounted on the carrier board, at least one semiconductor chip received in the through hole of the support board and mounted on the carrier board, at least one circuit built-up structure electrically connected to the semiconductor chip and formed on the support board and the semiconductor chip, wherein the circuit built-up structure includes at least two insulating layers, a plurality of conductive vias formed in the lower insulating layer, circuit layer electrically connected to the conductive vias and flush with the upper insulating layer, and a plurality of conductive elements mounted on the circuit built-up structure, such that the semiconductor chip can be electrically connected to an external device through the circuit built-up structure and the conductive elements.

### CROSS-REFERENCE TO RELATED APPLICATION

This application claims benefit under 35 USC 119 of Taiwan Application No. 094100802, filed Jan. 12, 2005.

### FIELD OF THE INVENTION

The present invention relates to a superfine-circuit semiconductor package structure, and more particularly, to a superfine-circuit semiconductor package structure that combines a carrier board, a semiconductor chip, and a circuit structure.

### BACKGROUND OF THE INVENTION

Development of semiconductor package technology brings a variety of semiconductor packages. For instance, Ball Grid Array (BGA) packaging, which represents an advanced semiconductor packaging technology, involves mounting a semiconductor chip on a substrate, implanting a grid-like array of solder balls on the bottom of the substrate by self-alignment, and forming electrical and mechanical bridges between the package and the printed circuit board by means of the solder balls; in so doing, relatively more I/O connections are disposed on a semiconductor chip carrier with a view to increasing integration on a semiconductor chip.

FIG. 1 is a cross-sectional schematic diagram of a Cavity-Down Ball Grid Array (CDBGA) semiconductor package according to the prior art. A Cavity-Down Ball Grid Array, which is a special form of ball grid array package structure, features a cavity formed in a substrate and a die placed in the cavity. A known ball grid array package structure 10 comprises a substrate 11, a carrier board 12, at least one semiconductor chip 13, a plurality of bonding wires 14, an encapsulant 15, and a plurality of solder balls 16. The substrate 11 is formed with at least one through hole 111. The carrier board 12 is coupled to the front of the substrate 11 such that the through hole 111 of the substrate 11 is formed with a cavity facing downward. During an assembly process, the semiconductor chip 13 is placed in the through hole 111 of the substrate 11 in an inverted manner such that a non-circuit surface of the semiconductor chip 13 abuts against and adheres to the carrier board 12. Then, in a wire bonding process, the bonding wires 14 electrically connect the semiconductor chip 13 to electrical connection pads disposed on the substrate 11. Then, in an encapsulation process, the encapsulant 15 is formed so as to totally enclose the semiconductor chip 13 and the bonding wires 14. Then, in a ball implanting process, the plurality of solder balls 16 are implanted on the bottom of the substrate 11, finalizing the fabrication of the cavity-down ball grid array package structure 10.

Although the aforesaid package solves the problems of heat dissipation and shielding by means of the carrier board, it does have its own drawbacks. In order to bond a solder ball to the printed circuit board smoothly, the solder ball is typically disposed at a height greater than the height of the loop of the corresponding wire, thus lessening the routability of the substrate and limiting the height at which the solder balls are disposed. Owing to the densely distributed looped wires surrounding the chip, the wires are likely to touch each other and thereby result in shorting between the wires, making wire bonding increasingly difficult. During a molding and sealing process, a substrate fully disposed with chips and wires is placed in a package mold, and then the package mold is filled with an epoxy resin material for formation of the encapsulant required to enclose the chips and the wires. In practice, subject to the design of the semiconductor package, the package mold inevitably varies in dimensions and clamping/pressing positions and thereby cannot be tightly clamped and secured in position, and in consequence the encapsulant is likely to spill on the substrate surface, leading to two disadvantages: first, the semiconductor package surface is less likely to be even and esthetic; second, contamination may occur to a portion of the substrate formed with bond pads for implanting the solder balls, and thus compromising the quality of the electrical connection of the semiconductor package. And further, during the filling process the resin material is a fluid, and mold fill pressure is exerted on the wire electrically connecting the chip and the substrate while the cavity is being filled with the resin material; in case of improper control over filling speed, the wires are prone to being swept by the mold flow, and in consequence the wires touch each other and result in short circuits, leading to deterioration of the quality and reliability of the semiconductor package.

In order to meet the demand for sophisticated electronic products and built-up substrates carrying increasingly fine circuits, existing fine circuit technology enables mass production of wires with line width and space respectively equal to 20 μm. However, the existing fine circuit technology is becoming less suitable for a semi-additive process; for instance, mass production of wires with line width and space rexpectively less than 10 μm by the existing fine circuit technology fails to achieve required dimension precision but incurs high costs. In addition, the trend of fine circuit technology is to have an increasingly small boundary surface between a circuit structure and an insulating layer, as far as a substrate is concerned. In order to form a fine circuit structure perfectly affixed to an insulating layer, the insulating layer must have a smooth, even surface before the formation of the fine circuit structure thereon, otherwise circuit layers subsequently disposed on the insulating layer is likely to peel off, ending up with deteriorated reliability. For instance, in order to form a circuit built-up structure on a substrate having an inner-layer patterned circuit, it is necessary to dispose an insulating layer on the substrate having the inner-layer patterned circuit before forming the circuit layers on the insulating layer. In practice, the uneven surface of the inner-layer patterned circuit formed in the substrate inevitably causes the surface of the insulating layer disposed on the substrate to be uneven. Similarly, the built-up circuit layers formed on the insulating layer having the uneven surface cannot be perfectly affixed to the insulating layer because of the uneven surface of the insulating layer but may even peel off. The smaller the boundary surface between the built-up circuit layers and the insulating layer is, the more serious is the aforesaid phenomenon associated with formation of a fine circuit structure.

In general, a semiconductor device process begins with a chip carrier manufacturer's production of chip carriers (for example, substrates and leadframes) fit for the semiconductor device. The chip carrier production is followed by processes performed by a semiconductor package manufacturer, namely die mounting, wire bonding, molding, and interconnection. All the processes have to be completed before the semiconductor device can provide the electronic functionalities wanted by the client end. The processes involve various process manufacturers (including chip carrier manufacturers and semiconductor package manufacturers), and thus the fabrication process not only comprises complicated steps but also uses incompatible interfaces. And further, if the client end intends to change a function or a design, the involved change and the required integration will be extremely intricate. Accordingly, the fabrication process fails to be flexible, and cost-efficient.

### SUMMARY OF THE INVENTION

In the light of the above-mentioned drawbacks of the prior art, it is a primary objective of the present invention to provide a superfine-circuit semiconductor package structure for combining a chip carrier manufacturing process with a chip packaging process with a view to meeting a flexibility need at client end and streamlining semiconductor processes and interface integration.

Another objective of the present invention to provide a superfine-circuit semiconductor package structure for forming a fine circuit structure with a view to exercising precise control over product dimensions.

Yet another objective of the present invention is to provide a superfine-circuit semiconductor package structure for providing strong adherence between a circuit structure and an insulating layer with a view to maintaining a high level of process reliability.

A further objective of the present invention is to provide a superfine-circuit semiconductor package structure for efficiently dissipating heat generated by a semiconductor chip in operation, and providing electromagnetic shielding so as to minimize electromagnetic interference and noise interference from an external device.

A further objective of the present invention is to provide a superfine-circuit semiconductor package structure for solving the drawbacks of a conventional semiconductor packaging process, namely encapsulant spilling in a molding process, and layouts of conductive elements for a semiconductor chip, with a view to enhancing production quality and product reliability of a semiconductor device.

To achieve the above-mentioned and other objectives, the present invention discloses a superfine-circuit semiconductor package structure which comprises a carrier board, a support board, at least one semiconductor chip, and at least one circuit built-up structure. The support board has at least one through hole and is mounted on the carrier board. The at least one semiconductor chip is received in the through hole of the support board and is mounted on the carrier board. The at least one circuit built-up structure is electrically connected to the semiconductor chip and is formed on the support board and the semiconductor chip. The circuit built-up structure comprises at least two insulating layers, a plurality of conductive vias formed in the lower insulating layer, circuit layers electrically connected to the conductive vias and flush with the upper insulating layer, and a plurality of conductive elements mounted on the circuit built-up structure. The circuit built-up structure is electrically connected to the semiconductor chip and the circuit layers through the conductive vias such that the semiconductor chip is electrically extended outward through the conductive vias and the circuit layers.

The superfine-circuit semiconductor package structure of the present invention combines a chip carrier (a circuit board) manufacturing process with a semiconductor chip packaging process with a view to streamlining the conventional semiconductor processes and interface integration. The superfine-circuit semiconductor package structure of the present invention streamlines a process and reduces costs by absolving a semiconductor process from wire bonding, a complicated flip chip related process, and process equipment required for electrical connection between a chip and a carrier structure thereof, which are otherwise necessary for the conventional semiconductor processes. The circuit built-up structure of the present invention uses a plurality of insulating layers such that openings configured for disposing the circuit layer is formed in the upper insulating layer and then vias penetrating the lower insulating layer is formed in the openings; in so doing, subsequently, the conductive vias are formed in the lower insulating layers, whereas the circuit layer is formed in the upper insulating layer. As a result, the circuit layer is perfectly affixed to the insulating layer so as to maintain a high level of reliability, and allow the circuit layer to be flush with the upper insulating layer such that the circuit built-up structures can be stacked on each other evenly. Accordingly, the objectives of a fine circuit manufacturing process are achieved.

The present invention provides at least one semiconductor chip mounted on a carrier board through a heat conduction adherence layer. Heat generated by the semiconductor chip in operation is efficiently dissipated. The carrier board, which is typically made of metal, efficiently provides electromagnetic shielding for the semiconductor device. The semiconductor chip is received in an through hole disposed in a metal board, an insulation board, or a circuit board mounted on the carrier board so as to reduce the overall thickness of the semiconductor device and thereby keep the semiconductor device small and compact. At least one stacking circuit structure is directly formed on the support board receiving the semiconductor chip so as to allow the semiconductor chip to electrically extend outward. At last, an edge of the stacking circuit structure is implanted with a plurality of conductive elements, such as solder balls, bonding pillars, and conductive pillars, so as to allow the package structure of the integrated chip to be electrically connected to an external device.

### BRIEF DESCRIPTION OF DRAWINGS

The invention can be more fully understood by reading the following detailed description of the preferred embodiments, with reference made to the accompanying drawings, wherein:

FIG. 1 (PRIOR ART) is a cross-sectional schematic diagram of a CDBGA semiconductor package;

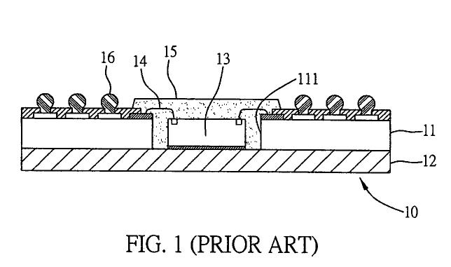

FIGS. 2A to 2H are cross-sectional schematic diagrams showing how to fabricate a superfine-circuit semiconductor package structure in accordance with the present invention;

FIG. 3 is a cross-sectional schematic diagram showing how to implement electrical extension of circuit built-up structures to a metal board in a superfine-circuit semiconductor package structure in accordance with the present invention; and

FIG. 4 is a cross-sectional schematic diagram of the second embodiment of a superfine-circuit semiconductor package structure in accordance with the present invention.

### DETAILED DESCRIPTION OF PREFERRED EMBODIMENTS

The following specific embodiments are provided to illustrate the disclosure of the present invention, these and other advantages and effects can be apparently understood by those skilled in the art after reading the disclosure of this specification. The present invention can also be performed or applied by other different embodiments. The details of the specification may be modified or changed on the basis of different points and applications without departing from the spirit of the present invention.

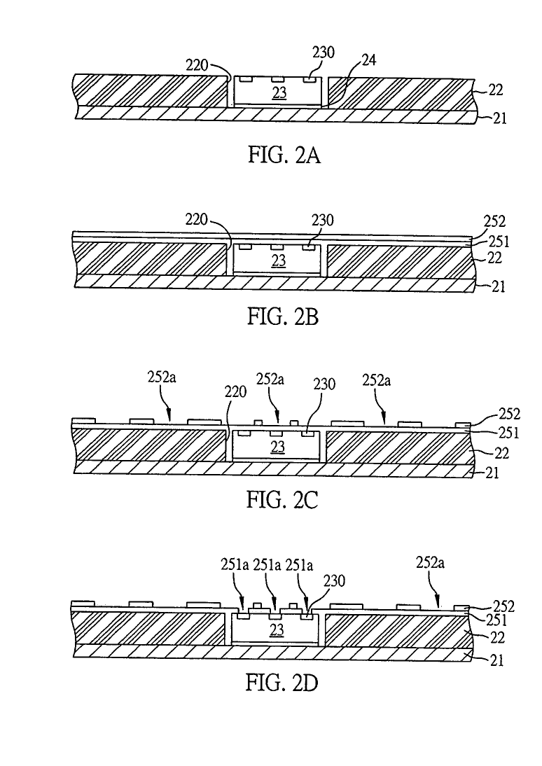

FIGS. 2A to 2H are cross-sectional schematic diagrams showing how to fabricate a superfine-circuit semiconductor package structure in accordance with the present invention.

As shown in FIG. 2A, the present invention provides a carrier board 21 on which a support board 22 with a through hole 220 is mounted. At least one semiconductor chip 23 is mounted on the carrier board 21 and received in the through hole 220 of the support board 22. The support board 22 is one selected from the group consisting of a metal board, an insulating board, and a circuit board. The at least one through hole 220 formed in and penetrating the support board 22 opens on the support board 22. The carrier board 21 seals another end of the through hole 220 so as to form a cavity. The at least one semiconductor chip 23 is received in the through hole 220 of the support board 22 and mounted on the carrier board 21 through a heat conduction adherence layer 24, such that electrode pads 230 disposed on a circuit surface of the semiconductor chip 23 are exposed through the through hole 220. Where the support board 22 is a metal board, the support board 22 is made of a material selected from the group consisting of copper, magnesium, aluminum, nickel, stainless steel, and an alloy thereof. Where the support board 22 is an insulating board, the support board 22 is made of a material selected from the group consisting of ceramic, epoxy resin, polyimide, cyanate ester, carbon fiber, bismaleimide triazine (BT), and a mixture of epoxy resin and glass fiber. Where the support board 22 is a circuit board, the support board 22 is pre-processed and comprises circuit layers.

As shown in FIG. 2B, a first insulating layer 251 and a second insulating layer 252 are successively formed on the support board 22 and the semiconductor chip 23, wherein filled with the first insulating layer 251 is a gap between the semiconductor chip 23 and the through hole 220 of the support board 22. The first insulating layer 251 and the second insulating layer 252 are made of materials in the following ways: both the first and the second insulating layers are made of either a light sensitive material or a non-light sensitive material, and alternatively one of the two insulating layers is made of the light sensitive material and the other insulating layer of the non-light sensitive material.

As shown in FIG. 2C, a patterning process is performed on the second insulating layer 252 so as to form a plurality of openings 252a therein. Forming the plurality of openings 252a in the second insulating layer 252 and thereby exposing a portion of the first insulating layer 251 are implemented by exposure, development, etching, and using the first insulating layer 251 as a stop layer.

As shown in FIG. 2D, vias 251a are formed in the first insulating layer 251 by laser drilling, plasma etching, and etc. so as to allow the electrode pads 230 to be exposed through the vias 251a.

As shown in FIG. 2E, a conductive layer 26 is formed on an exposed portion of the first and second insulating layers 251 and 252 and the electrode pads 230. The conductive layer 26 serves as a conductive path required for an electroplating process whereby a metal conductor structure 27 is formed on the conductive layer 26. The conductive layer 26 is made of either metal or conductive polymer.

As shown in FIG. 2F, with a process of polishing or etching, a portion of the metal conductor structure 27 and a portion of the conductive layer 26 are removed from the second insulating layer 252 such that the second insulating layer 252 is flush with residues of the metal conductor structure 27 remaining in the plurality of openings 252a, allowing a subsequently superimposed circuit structure to lie flat and facilitating a fine circuit fabrication process. The residues of the metal conductor structure 27 remaining in the vias 251a are referred to as conductive vias 271. The residues of the metal conductor structure 27 remaining in the plurality of openings 252a are referred to as circuit layers 270. The circuit layer 270 is electrically connected to the electrode pads 230 disposed on the semiconductor chip 23 through the conductive vias 271, forming a circuit built-up structure 27a.

As shown in FIG. 2Q the circuit built-up structure 27a is formed as follow. The circuit built-up structure 27a is provided with the plurality of insulating layers (the first and second insulating layers 251 and 252). The second insulating layer 252 is formed with the openings 252a which are configured for disposing the circuit layers 270. Then, the vias 251a are formed in the openings 252a such that the vias 251a penetrates the first insulating layer 251. Finally, electroplating is performed, so as to form the conductive vias 271 with a view to perfectly affixing the circuit layers 270 to the first insulating layer 251, maintaining a high level of process reliability, allowing the circuit layers 270 to be flush with a top surface of the second insulating layer 252 such that the circuit built-up structures 27a are mounted on each other evenly. Accordingly, the objectives of a fine circuit manufacturing process are achieved.

As shown in FIG. 2H, the top circuit built-up structure 27a is covered with a solder mask layer 28 which undergoes a patterning process to form openings for holding conductive elements 29, such as solder balls and conductive pillars.

Referring to FIG. 2H again, the superfine-circuit semiconductor package structure of the present invention comprises a carrier board 21, a support board 22, at least one semiconductor chip 23, and at least one circuit built-up structure 27a. The support board 22 has at least one through hole 220 and is mounted on the carrier board 21. The at least one semiconductor chip 23 is mounted on the carrier board 21 and is received in the through hole 220 of the support board 22. The at least one circuit built-up structure 27a is electrically connected to the semiconductor chip 23 and is formed on the support board 22 and the semiconductor chip 23. The circuit built-up structure 27a comprises at least two insulating layers 251 and 252, a plurality of conductive vias 271 formed in the lower insulating layer (the first insulating layer 251 as shown in FIG. 2H), the circuit layers 270 electrically connected to the conductive vias 271 and flush with the upper insulating layer (the second insulating layer 252 as shown in FIG. 2H), and a plurality of conductive elements 29 mounted on the circuit built-up structure 27a. The circuit built-up structure 27a is electrically connected to the semiconductor chip 23 and the circuit layers 270 through the conductive vias 271 such that the semiconductor chip 23 is electrically extended outward through the conductive vias 271 and the circuit layers 270.

The carrier board 21 is made of a material selected from the group consisting of copper, aluminum, magnesium, nickel, an alloy thereof, stainless steel, and ceramic. Also, a corrugated structure (not shown) can be disposed on the outer surface of the carrier board 21, so as to increase the effective heat dissipation area and the heat conduction efficiency of the carrier board 21.

The support board 22 can be a metal board, such that the metal board and the carrier board 21 are made of either the same material or different materials. Where both the support board 22 and the carrier board 21 are made of the same material, it is feasible to combine the support board 22 with the carrier board 21: for instance, etching a thick metal plate to form at least one cavity therein, and mounting at least one semiconductor chip in the cavity. Also, the support board 22 can be an insulating board made of one selected from the group consisting of ceramic, organic material, and fiber-enhanced organic material, such as epoxy resin, polyimide, bismaleimide triazine (BT), cyanate ester, FR-4 resin, and FR-5 resin. The insulating board is secured to the carrier board 21 through a glue layer or by compression. Of course, the support board 22 may also be a circuit board.

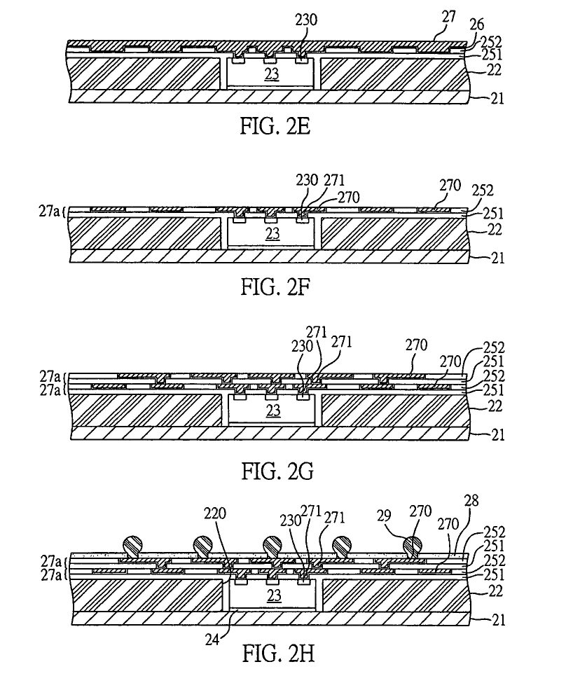

Refer to FIG. 3. In the event that the support board 22 is a metal board, the metal board can function as a grounding element by allowing conductive structures 30, such as conductive vias, to extend from the circuit built-up structure 27a to the metal board. Alternatively, where the support board 22 is a circuit board or is embedded with a passive device, conductive structures 30, such as conductive vias, may extend from the circuit built-up structure 27a and thereby be electrically connected to the circuit board. In so doing, the package structure of the present invention provides better electrical functions.

The semiconductor chip 23 comprises a circuit surface and an opposing surface. On the circuit surface, the electrode pads 230 are formed. The opposing surface, coupled with a heat conduction adherence layer 24, allows the semiconductor chip 23 to be mounted on the carrier board 21 and received in the through hole 220 of the support board 22. The heat conduction adherence layer 24 and the carrier board 21 together function as a heat dissipation path for dissipating heat generated by the semiconductor chip 23 in operation. The carrier board 21 provides electromagnetic shielding.

The circuit built-up structure 27a comprises the first insulating layer 251, the second insulating layer 252, the conductive vias 271 formed in the first insulating layer 251, and the circuit layers 270 electrically connected to the conductive vias 271 and flush with the second insulating layer 252. The circuit layers 270 are electrically connected to the electrode pads 230 disposed on the semiconductor chip 23 through the conductive vias 271; in other words, the semiconductor chip 23 is electrically extended outward through the conductive vias 271 and the circuit layers 270.

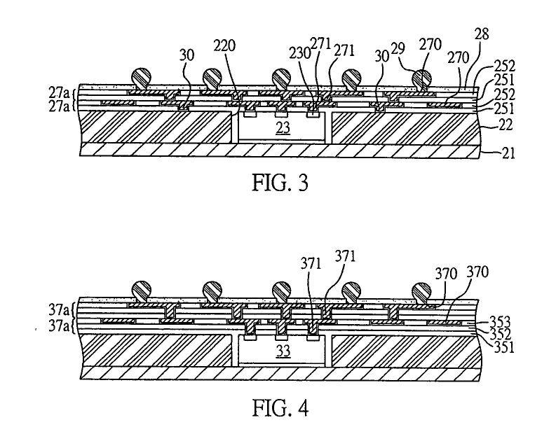

FIG. 4 is a cross-sectional schematic diagram of the second embodiment of a superfine-circuit semiconductor package structure in accordance with the present invention. As shown in FIG. 4, on the whole, the package structure of the second embodiment is the same as that of the first embodiment in accordance with the present invention except that, in the second embodiment, the number of insulating layers in a circuit built-up structure 37a is not necessarily two; instead, the second embodiment discloses that it is feasible to use three or more insulating layers 351, 352 and 353, wherein conductive vias 371 of the circuit built-up structure 37a are formed in the bottom and middle insulating layers (corresponding to the first and second insulating layers 351 and 352 shown in the drawing), and circuit layers 370 are electrically connected to the conductive vias 371, formed in openings of the top insulating layer (corresponding to the third insulating layer 353 shown in the drawing) and flush with the top insulating layer. The circuit built-up structure 37a is electrically connected to a semiconductor chip 33 and the circuit layers 370 through the conductive vias 371. In addition, the second insulating layer 352 may be configured to function as a stop layer for stopping exposure, development, and etching in a patterning process or as a barrier layer for preventing migration of copper ions, such that circuits of the circuit built-up structure 37a lie flat and electrical conduction functions well.

The superfine-circuit semiconductor package structure of the present invention combines a circuit board manufacturing process with a semiconductor chip packaging process with a view to streamlining the conventional semiconductor processes and interface integration. The superfine-circuit semiconductor package structure of the present invention streamlines a process and reduces costs by absolving a semiconductor process from wire bonding, a complicated flip chip related process, and process equipment required for electrical connection between a chip and a carrier structure thereof, which are otherwise necessary for the conventional semiconductor processes. The circuit built-up structure of the present invention uses a plurality of insulating layers such that openings configured for disposing the circuit layer are formed in the upper insulating layer and then vias penetrating the lower insulating layer are formed in the openings; in so doing, subsequently, the conductive vias are formed in the lower insulating layer, whereas the circuit layer is formed in the upper insulating layer. As a result, the circuit layer is perfectly affixed to the insulating layer so as to maintain a high level of reliability, and allow the circuit layer to be flush with the upper insulating layer such that the circuit built-up structures can be stacked on each other evenly. Accordingly, the objectives of a fine circuit manufacturing process are achieved. The present invention provides at least one semiconductor chip mounted on a carrier board through a heat conduction adherence layer. Heat generated by the semiconductor chip in operation is efficiently dissipated. The carrier board, which is typically made of metal, efficiently provides electromagnetic shielding for the semiconductor device. The semiconductor chip is received in an through hole disposed in a metal board, an insulating board, or a circuit board mounted on the carrier board so as to reduce the overall thickness of the semiconductor device and thereby keep the semiconductor device small and compact. At least one stacking circuit structure is directly formed on the support board receiving the semiconductor chip so as to allow the semiconductor chip to electrically extend outward. At last, an edge of the stacking circuit structure is implanted with a plurality of conductive elements, such as solder balls, bonding pillars, and conductive pillars, so as to allow the package structure of the integrated chip to be electrically connected to an external device.

The foregoing embodiments are only illustrative of the features and functions of the present invention but are not intended to restrict the scope of the present invention. It is apparent to those skilled in the art that all modifications and variations made in the foregoing embodiments according to the spirit and principle in the disclosure of the present invention should fall within the scope of the appended claims.

What is claimed is:

1. A superfine-circuit semiconductor package structure, comprising:
a carrier board;
a support board having at least one through hole and mounted on the carrier board;
at least one semiconductor chip mounted on the carrier board and received in the through hole of the support board; and
at least one circuit built-up structure formed on the support board and the semiconductor chip and electrically connected to the semiconductor chip, wherein the circuit built-up structure comprises at least two neighboring upper-lower insulating layer, a plurality of conductive vias formed in the lower insulating layer, and circuit layer electrically connected to the conductive vias, disposed in openings of the upper insulating layer and flush with the upper insulating layer.

2. The superfine-circuit semiconductor package structure of claim 1, further comprising a plurality of conductive elements mounted on the circuit built-up structure.

3. The superfine-circuit semiconductor package structure of claim 1, wherein the conductive vias are electrically connected to the semiconductor chip and the circuit layers such that the semiconductor chip is electrically extended outward through the conductive vias and the circuit layers.

4. The superfine-circuit semiconductor package structure of claim 1, wherein the support board is one selected from the group consisting of a metal board, an insulating board, and a circuit board.

5. The superfine-circuit semiconductor package structure of claim 1, wherein the semiconductor chip is mounted on the carrier board through a heat conduction adherence layer.

6. The superfine-circuit semiconductor package structure of claim 1, wherein on the semiconductor chip are a plurality of electrode pads for electrical connection with the conductive vias.

7. The superfine-circuit semiconductor package structure of claim 1, wherein filled with the insulating layers is a gap between the semiconductor chip and the through hole of the support board.

8. The superfine-circuit semiconductor package structure of claim 1, wherein the insulating layers are made of materials comprising a light sensitive material and a non-light sensitive material.

9. The superfine-circuit semiconductor package structure of claim 1, wherein extended from the circuit built-up structure to the support board are conductive structures.

10. The superfine-circuit semiconductor package structure of claim 1, wherein the insulating layers comprise an upper insulating layer in which the circuit layer is formed and a lower insulating layer in which the conductive vias are formed.

11. The superfine-circuit semiconductor package structure of claim 1, wherein the insulating layers comprise three insulating layers, namely a middle insulating layer and a bottom insulating layer in both of which the conductive vias are formed, and a top insulating layer in which the circuit layers are formed.

12. The superfine-circuit semiconductor package structure of claim 11, wherein the middle insulating layer is configured to function as a stop layer for stopping exposure, development, and etching in a patterning process and as a barrier layer for preventing migration of copper ions.
